(19) United States
(12) Patent Application Publication
(10) Pub. No.: US 2024/0178119 A1
(43) Pub. Date: May 30, 2024

(54) RBTV IMPROVEMENT FOR GLASS CORE ARCHITECTURES

(71) Applicant: Intel Corporation, Santa Clara, CA (US)

(72) Inventors: Mohammad Mamunur RAHMAN, Gilbert, AZ (US); Jeremy D. ECTON, Gilbert, AZ (US); Gang DUAN, Chandler, AZ (US)

(21) Appl. No.: 18/071,116

(22) Filed: Nov. 29, 2022

(51) Int. Cl. H01L 23/498; H01L 23/00; H01L 23/13; H01L 23/15; H01L 23/538

(52) U.S. Cl. CPC H01L 23/49838; H01L 23/13; H01L 23/15; H01L 23/49822; H01L 23/49866; H01L 23/5381; H01L 24/13; H01L 24/16; H01L 24/17; H01L 23/49816; H01L 23/49833; H01L 23/5385; H01L 2224/13111; H01L 2224/1601; H01L 2224/16055; H01L 2224/16058; H01L 2224/16059; H01L 2224/16227; H01L 2224/1703; H01L 2224/17055; H01L 2224/17152; H01L 2224/17153; H01L 2924/37001

(57) ABSTRACT

Embodiments disclosed herein include an interconnect. In an embodiment, the interconnect comprises a substrate and a pad over the substrate. In an embodiment, a hole is provided through the pad. In an embodiment, the hole exposes a portion of the substrate. In an embodiment, a solder is provided over the pad, and the solder bridges across the hole through the pad.

### TECHNICAL FIELD

Embodiments of the present disclosure relate to electronic packages, and more particularly to packaging architectures with core bumps with holes and bridge bumps without holes.

### BACKGROUND

In advanced electronic packaging architectures multiple dies are stitched together. This die stitching allows for the overlying dies to have a smaller footprint while maintaining high computing performance. Shrinking the die size improves die yield and therefore can aid in cost reduction. However, stitching the dies together is not a simple task. Particularly, a bridge die embedded in the package substrate will have high density routing in order to communicatively couple together a pair of dies. The high density routing requires bumps (also referred to as bridge bumps) with a small pitch and critical dimension.

Particularly, the bridge die bump pitch and critical dimension is significantly smaller than the bump pitch and critical dimension of the bumps (also referred to as core bumps) that couple the dies to the package substrate. The variation in bump size between the bridge bumps and the core bumps results in uneven bump heights after reflow. This variation, sometimes referred to as average bump thickness variation (rBTV) can lead to assembly issues. In one instance a fly-cutting process is used to reduce rBTV. However, such processes introduce another processing step into the process flow, which increases cost of assembly. Additionally, the fly-cutting process may not provide the desired rBTV values needed for high yielding advanced packaging applications, and prevents further scaling to smaller dimensions.

### BRIEF DESCRIPTION OF THE DRAWINGS

FIG. 1A is a cross-sectional illustration of a bridge bump and a core bump with plated solder.

FIG. 1B is a cross-sectional illustration of a bridge bump and a core bump with reflown solder that results in high bump thickness variation (BTV).

FIG. 2A is a cross-sectional illustration of a bridge bump and a core bump with a hole and plated solder, in accordance with an embodiment.

FIG. 2B is a plan view illustration of the package substrate in FIG. 2A, in accordance with an embodiment.

FIG. 2C is a cross-sectional illustration of a bridge bump and a core bump with reflown solder, in accordance with an embodiment.

FIG. 2D is a plan view illustration of the package substrate in FIG. 2C, in accordance with an embodiment.

FIG. 3A is a cross-sectional illustration of a package substrate with a core bump that includes a hole through a thickness of the core bump, in accordance with an embodiment.

FIG. 3B is a cross-sectional illustration of a reflown solder over a core bump that includes a hole through a thickness of the core bump, in accordance with an embodiment.

FIG. 3C is a cross-sectional illustration of a reflown solder over a core bump with a hole where the reflown solder only partially fills the hole, in accordance with an embodiment.

FIG. 4 is a cross-sectional illustration of an electronic package with a die coupled to a package substrate through a core bump and a bridge bump.

FIG. 5 is a plan view illustration of an electronic package with an embedded bridge that includes bridge bumps and core bumps that include a hole, in accordance with an embodiment.

FIGS. 6A-6F are cross-sectional illustrations that show a process for attaching dies to a package substrate using core bumps with holes and bridge bumps, in accordance with an embodiment.

FIG. 7 is a cross-sectional illustration of an electronic system that includes an electronic package with core bumps that have holes and bridge bumps, in accordance with an embodiment.

FIG. 8 is a schematic of a computing device built in accordance with an embodiment.

### EMBODIMENTS OF THE PRESENT DISCLOSURE

Described herein are packaging architectures with core bumps with holes and bridge bumps without holes, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, advanced electronic packaging architectures are beginning to use bridge dies in order to couple together overlying dies. For example, a pair of compute dies may be communicatively coupled together using a bridge die. Generally, the bumps on the bridge die have smaller critical dimension and pitch than the core bumps that connect the overlying dies to the package substrate. The bridge may have high density routing in order to couple the overlying dies together.

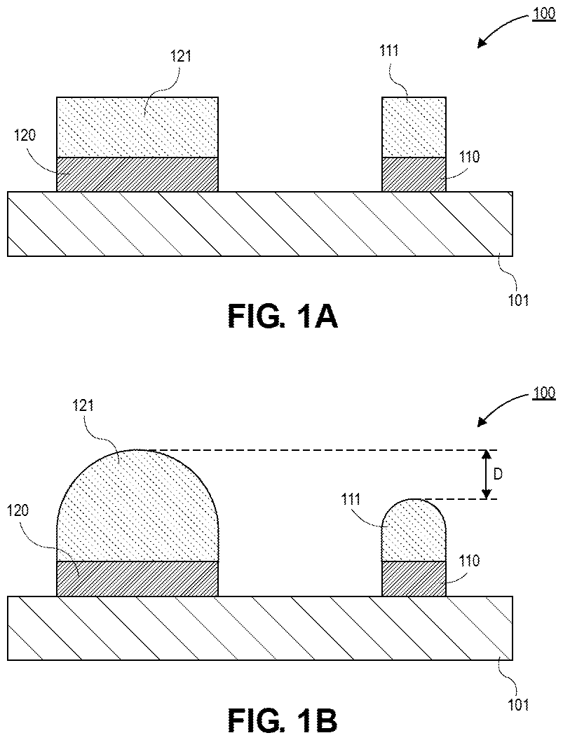

The differences in bump critical dimension between the bridge bumps and the core bumps can lead to significant assembly problems. Particularly, bump thickness variation (BTV) after solder reflow generates assembly issues. Generally, the smaller bridge bumps will have a smaller standoff height than the larger core bumps. An example of such a situation is shown in FIGS. 1A and 1B.

Referring now to FIG. 1A, a cross-sectional illustration of a portion of an electronic package 100 is shown. The electronic package 100 may include a package substrate 101. Conductive routing (not shown) may be included in the package substrate 101. Additionally, a bridge die (not shown) may occupy a region of the package substrate 101. For example, a bridge die may be below the first bump 110. The second bump 120 may be provided adjacent to the first bump 110. In other instances, the first bump 110 may be spaced away from the second bump 120. For example, the first bump 110 may be at a center of the package substrate 101, and the second bump 120 may be at an edge of the package substrate 101.

As shown, solder 111 and solder 121 is provided on the top surfaces of the first bump 110 and the second bump 120, respectively. As shown, the thicknesses of the solder 111 and the solder 121 are substantially similar to each other. This is because the solder 111 and 121 may be plated with a uniform solder plating process. Since the first bump 110 and the second bump 120 have the same thickness, the standoff height of both solders 111 and 121 may be substantially similar to each other.

Referring now to FIG. 1B, a cross-sectional illustration of the electronic package 100 after a solder reflow operation is shown. As illustrated, the solder 111 and 121 reflow so that the top surfaces are rounded. This is due to the effects of surface tension on the bumps 110 and 120. However, the standoff heights are no longer uniform. For example, the solder 121 may have a standoff height that is greater than the standoff height of the solder 111. Particularly, the difference in standoff heights may be represented by a difference D. The difference D in the standoff heights negatively impacts average bump thickness variation (rBTV). This negatively impacts assembly performance and can lead to yield issues.

Accordingly, embodiments disclosed herein include bump architectures that minimize rBTV. Particularly, the larger core bumps include a hole through their center. That is, the core bumps may be referred to as ring shaped since the hole generates a ring like architecture. The hole may be used as a reservoir in order to hold a portion of the volume of the solder in order to minimize the difference D between the standoff heights of the core bumps and the bridge bumps. In some instances the solder completely fills the hole. In other embodiments, the solder partially fills the hole. Through analysis, modeling, and/or experimentation, the size of the hole can be modulated in order to provide an improved rBTV.

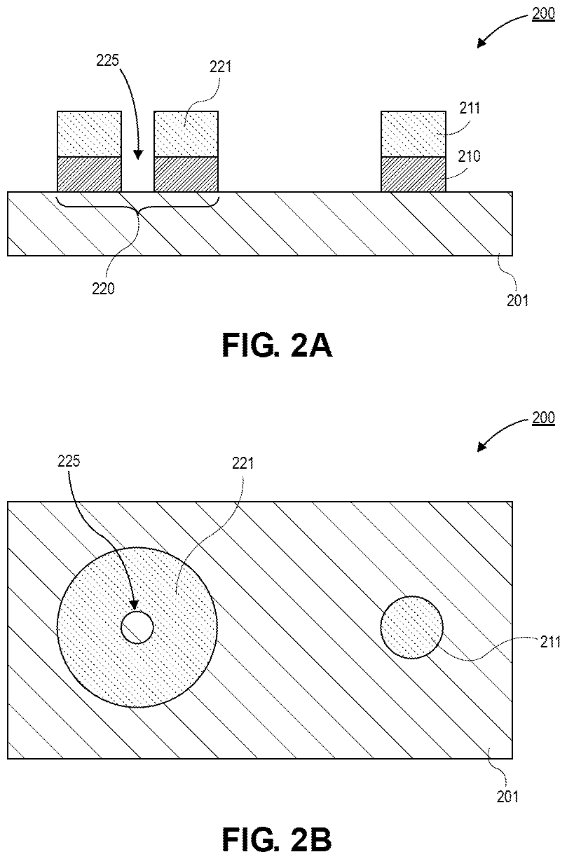

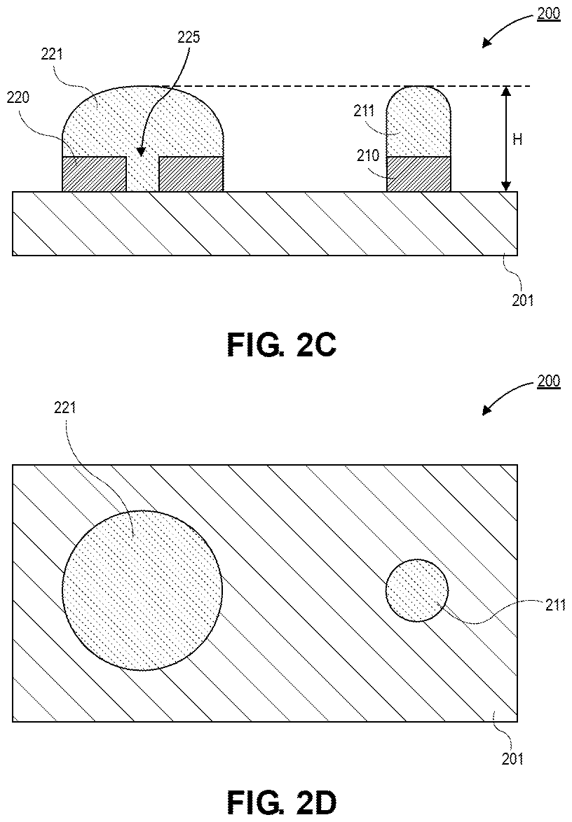

Referring now to FIG. 2A, a cross-sectional illustration of an electronic package 200 is shown, in accordance with an embodiment. The electronic package 200 may comprise a package substrate 201. The package substrate 201 may include a core and buildup layers over and under the core. The core may be a glass core, an organic core, or the like. However, in other embodiments the package substrate 201 may be a coreless package substrate 201. In an embodiment, the package substrate 200 may further comprise one or more embedded bridges (not shown). The architecture of embedded bridges is described in greater detail below.

In an embodiment, a first pad 210 and a second pad 220 may be provided on the package substrate. The first pad 210 and the second pad 220 may have different width dimensions. For example, the first pad 210 may be smaller than the second pad 220. In a particular embodiment, the first pad 210 may have a width that is up to approximately 40 μm, and the second pad 220 may have a width that is up to approximately 80 μm. Though, larger widths may also be used for either pad 210 and 220 in some embodiments. In an embodiment, a thickness of the first pad 210 and a thickness of the second pad 220 may be substantially similar. In an embodiment, solder 211 and solder 221 are plated on the top surfaces of the first pad 210 and the second pad 220, respectively. In the pre-reflow state shown in FIG. 2A, the solder 211 may have a thickness that is substantially equal to a thickness of the solder 221. In an embodiment, the first pad 210 and the second pad 220 comprise copper or another electrically conductive material.

In an embodiment, the second pad 220 may comprise a hole 225. The hole 225 may pass through an entire thickness of the second pad 220. That is, the underlying package substrate 201 may be exposed by the hole 225. The hole 225 may have any suitable dimension. Particularly the dimensions of the hole 225 may be chosen in order to ensure low rBTV after reflow, as will be described in greater detail below.

Referring now to FIG. 2B, a plan view illustration of the electronic package 200 is shown, in accordance with an embodiment. As shown, the solder 211 and the solder 221 have substantially circular shapes. As such, the underlying pads 210 and 220 may also have circular shapes. The second pad 220 may have a circular ring shape. That is, the second pad 220 may have an outer width and an inner width. While shown as being circular, it is to be appreciated that one or both of the first pad 210 and the second pad 220 may have different shapes (e.g., square, rectangular, oval, etc.). Additionally, the hole 225 in the second pad 220 may have a shape that is different than the outer shape of the second pad 220. For example, the outer shape of the second pad 220 may be circular, and the hole 225 may be rectangular or square shaped.

In the illustrated embodiment, the first pad 210 and the second pad 220 are adjacent to each other. In a particular embodiment, the first pad 210 may be on a bridge (not shown), and the second pad 220 may be directly on the package substrate 201. The first pad 210 may be referred to as a bridge bump, and the second pad 220 may be referred to as a core bump. In an embodiment, the first pad 210 may be proximate to a center of the package substrate 201, and the second pad 220 may be proximate to an outer edge of the package substrate 201.

Referring now to FIG. 2C, a cross-sectional illustration of the electronic package 200 after a reflow operation is shown, in accordance with an embodiment. In an embodiment, the electronic package 200 has reflown solder 211 and 221. As shown, the reflow process results in the top surfaces of the solder 211 and 221 being rounded or curved. However, in contrast to examples provided above, the standoff height of the solder 211 is substantially equal to the standoff height of the solder 221. For example, both the solder 211 and the solder 221 have a uniform standoff height H.

The uniform standoff height H is enabled by the presence of the hole 225 in the second pad 220. The hole 225 provides extra volume for the solder 221 to fill. Since the extra volume is directed downwards towards the package substrate 201, the top of the solder 221 does not extend up past the top of the solder 211. In an embodiment, the hole 225 is entirely filled by the solder 221. In other embodiments, the hole 225 is at least partially filled by the solder 221. In an embodiment, the solder 221 may be referred to as spanning across the width of the hole 225. The solder 221 may flow into the hole 225 as a result of surface tension forces, capillary forces, or the like.

Referring now to FIG. 2D, a plan view illustration of the electronic package 200 after the reflow is shown, in accordance with an embodiment. As shown, the solder 221 has filled the hole 225. In an embodiment, the solder 221 has at least spanned across the opening of the hole 225. Accordingly, from the top view, the solder 221 has a circular shape without any holes through to the package substrate 201.

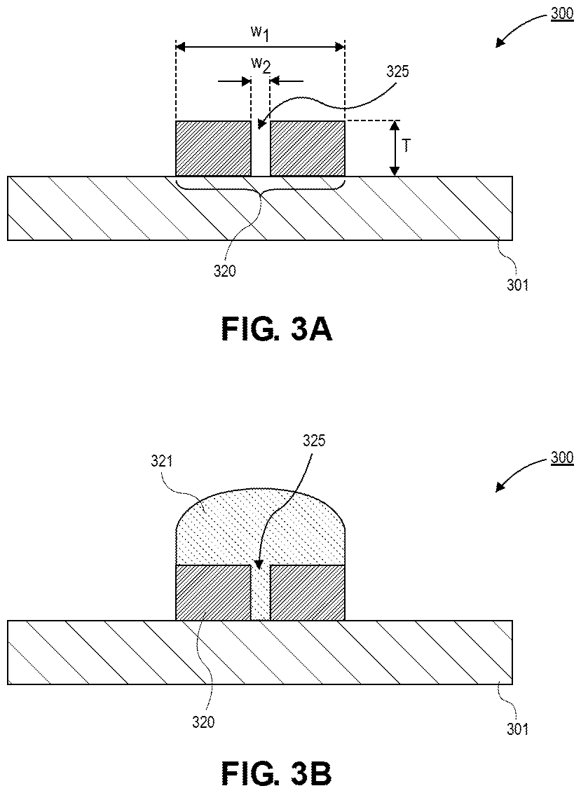

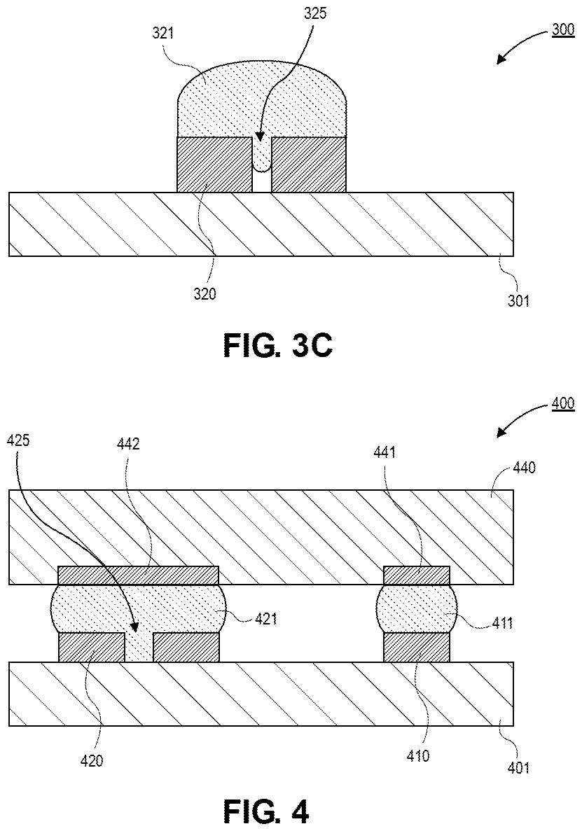

Referring now to FIG. 3A, a cross-sectional illustration of a second pad 320 in an electronic package 300 is shown, in accordance with an embodiment. In an embodiment, the second pad 320 may be provided over a package substrate 301. The package substrate 301 may be substantially similar to the package substrate 201 described in greater detail above. In an embodiment, the second pad 320 may comprise a thickness T. The thickness T may be up to approximately 25 μm in some embodiments. Though, thicker second pads 320 may be used in some embodiments. In an embodiment, the second pad 320 may include a first width W₁. The first width W₁ may be referred to as an outer width or an outer diameter (e.g., when the second pad 320 is circular). In an embodiment, the first width W₁ may be up to approximately 80 μm. Though, larger first widths W₁ may be used in some embodiments.

In an embodiment, the second pad 320 may comprise a hole 325. The hole passes through an entire thickness of the second pad 320. That is, the hole 325 may expose a portion of the package substrate 301 below the second pad 320. In an embodiment, the hole 325 may have a second width W₂. The second width W₂ is smaller than the first width W₁. The presence of the hole 325 results in the second pad 320 having a ring shaped structure. The second width W₂ may be equal to or smaller than the thickness T. In a particular embodiment, the second width W₂ may be up to approximately half the thickness T. In some embodiments, the hole 325 may be described as being a high aspect ratio feature. That is, a depth of the hole (i.e., the thickness T) may be three times as large as the second width W₂ or greater. In a particular embodiment, the second width W₂ may be up to approximately 15 μm. The dimensions of the hole 325 may be chosen in order to provide a desired standoff height for a solder that is provided over the second pad 320. For example, the dimensions of the hole 325 may be chosen based on modelling, experimentation, or the like.

Referring now to FIG. 3B, a cross-sectional illustration of the electronic package 300 after a solder 321 is deposited and reflown is shown, in accordance with an embodiment. As shown, the reflown solder 321 has a rounded or curved top surface. Additionally, the solder 321 spans across the top surface of the hole 325. As such, despite having a hole 325, the solder 321 forms a solid feature when viewed from the top, similar to what is shown in FIG. 2D.

In an embodiment, the reflown solder 321 may also at least partially fill the hole 325. In the embodiment shown in FIG. 3B, the solder 321 completely fills the hole 325. As such, a portion of the solder 321 may be in direct contact with the underlying package substrate 301. This is in contrast to a traditional pad where the pad is provided between the solder and the package substrate at all locations.

Referring now to FIG. 3C, a cross-sectional illustration of the electronic package 300 after a solder 321 is deposited and reflown is shown, in accordance with an additional embodiment. As shown, the reflown solder 321 has a rounded or curved top surface. Additionally, the solder 321 spans across the top surface of the hole 325. As such, despite having a hole 325, the solder 321 forms a solid feature when viewed from the top, similar to what is shown in FIG. 2D.

In an embodiment, the solder 321 partially fills the hole 325. That is, the solder 321 may extend down into the hole 325 from above the hole 325. This partial filling may result in a bottom region of the hole 325 being unfilled. As such, an air gap may be provided between the bottom of the solder 321 and the package substrate 301. The bottom of the solder 321 may be rounded in some embodiments due to surface tension effects.

Referring now to FIG. 4, a cross-sectional illustration of an electronic package 400 is shown, in accordance with an embodiment. In an embodiment, the electronic package 400 comprises a package substrate 401. The package substrate 401 may be substantially similar to the package substrate 201 described in greater detail above. In an embodiment, a die 440 is coupled to the package substrate 401. In a particular embodiment, the die 440 is coupled to the package substrate 401 through interconnects that comprise solder 421 and 411. The solder 411 and 421 may be provided between pads on the package substrate 401 and pads on the die 440. For example, the solder 411 may be provided between first pad 410 and pad 441, and the solder 421 may be provided between second pad 420 and pad 442.

In an embodiment, the first pad 410 may have a width that is less than a width of the second pad 420. Accordingly, rBTV can become an issue. In order to mitigate the differences in rBTV, a hole 425 is provided in the second pad 420. The hole 425 provides excess volume that the solder 421 can occupy in order to mitigate rBTV. As shown in FIG. 4, the solder 421 completely fills the hole 425 and contacts the surface of the package substrate 401. In other embodiments, the solder 421 at least partially fills the hole 425. The dimensions of the hole may be chosen in order to provide reflown solder 411 and 421 with substantially similar standoff heights. As such, the attachment of the overlying die 440 is simpler.

In an embodiment, the die 440 may be a compute die. For example, the die 440 may be a processor, a graphics processor, a system on a chip (SoC), an ASIC, or the like. The die 440 may also be a memory die or any other type of die. While a single die 440 is shown, it is to be appreciated that a plurality of dies may be coupled to the package substrate 401. In some instances a bridge (not shown) may communicatively couple together different dies. The first pad 410 may be provided over the bridge and the second pad 420 may be adjacent to the bridge.

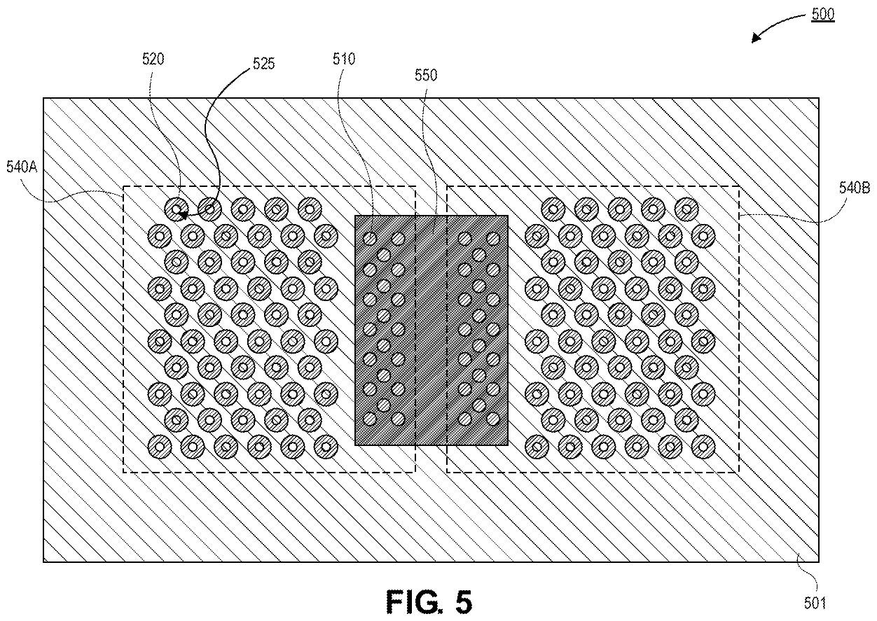

Referring now to FIG. 5, a plan view illustration of an electronic package 500 is shown, in accordance with an embodiment. The electronic package 500 may include a package substrate 501. The package substrate 501 may be substantially similar to the package substrate 201 described in greater detail above. In an embodiment, a bridge 550 may be embedded in the package substrate 501. The bridge 550 may include high density routing in order to communicatively couple a first die 540A to a second die 540B. The dies 540A and 540B are shown with dashed lines in order to indicate that they are above the package substrate 501.

In an embodiment, the footprint of the dies 540A and 540B may at least partially overlap the bridge 550. First pads 510 may be provided on the bridge 550 in order to connect to the dies 540A and 540B. In an embodiment, the first pads 510 may have a first dimension and spacing. For example, the width of the first pads 510 may be up to approximately 40 μm. Though, larger first pads 510 may also be used in some embodiments. Since the first pads 510 are on the bridge 550, they may alternatively be referred to as bridge pads 510.

In an embodiment, second pads 520 may be provided under the dies 540A and 540B, but outside the footprint of the bridge 550. The second pads 520 may be referred to as core pads in some embodiments. The second pads 520 may have a second dimension that is greater than the first dimension. For example, the second pads 520 may have a width that is up to approximately 80 μm. Though, larger widths may also be used for the second pads 520. In order to mitigate rBTV, holes 525 are provided in a center of the second pads 520. The holes 525 may extend through an entire thickness of the second pads 520 in order to expose the underlying package substrate 501.

In the illustrated embodiment, all of the holes 525 are shown as having the same dimension (e.g., diameter). However, in other embodiments, the holes 525 may have a variable dimension. For example, the holes 525 for pads towards the edge of the bump field may have a different diameter than the holes 525 for pads towards the center of the bump field. More generally, any systematic rBTV can be accounted for by varying the size of the holes 525.

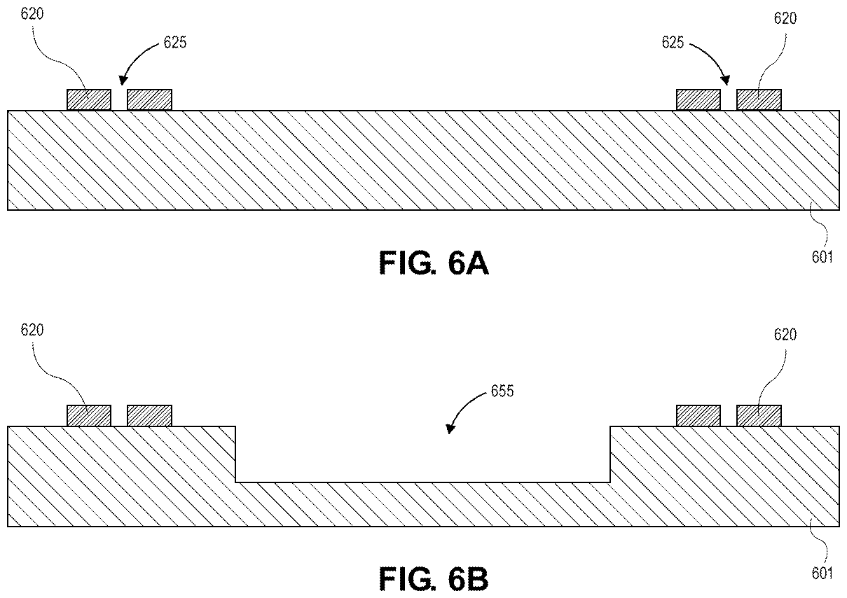

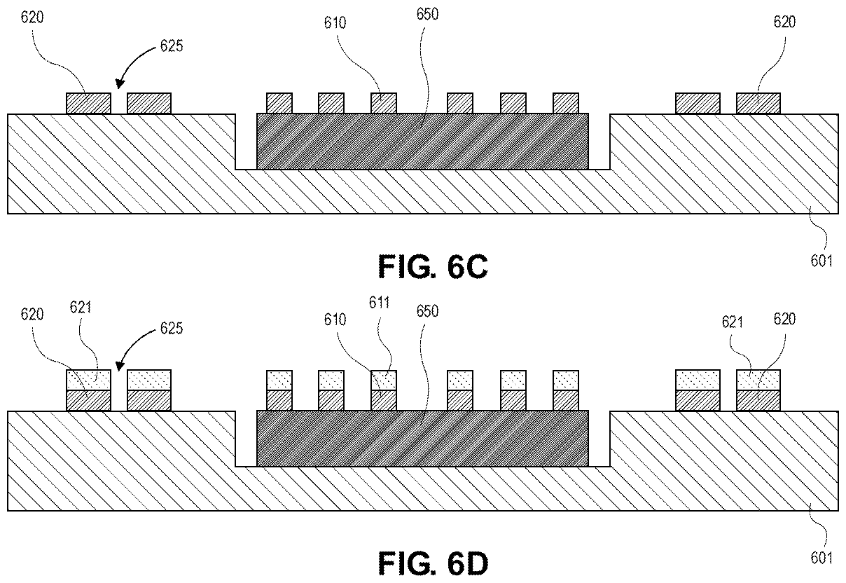

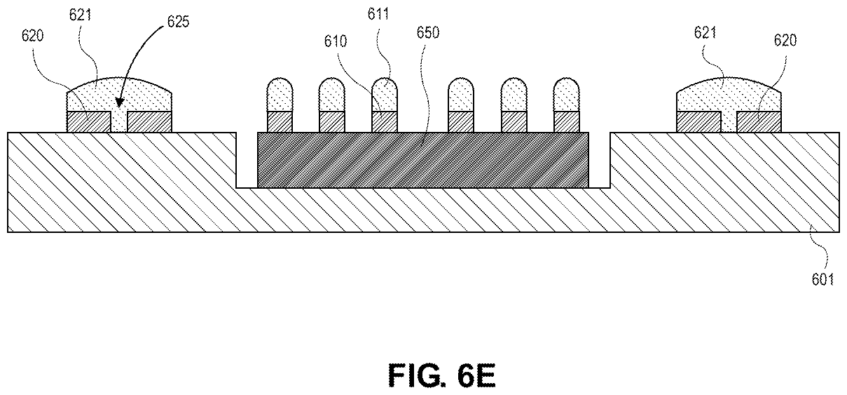

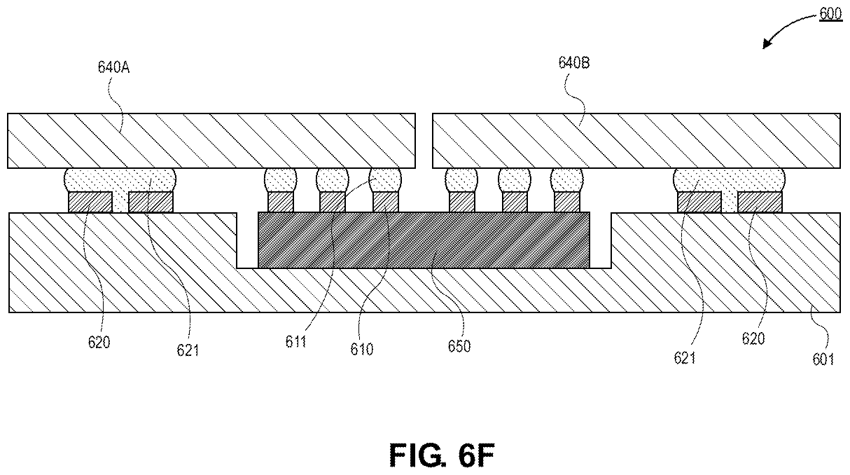

Referring now to FIGS. 6A-6F, a series of cross-sectional illustrations depicting a process for assembling an electronic package 600 is shown, in accordance with an embodiment. In an embodiment, the electronic package 600 may include a plurality of dies 640 that are coupled together by a bridge 650.

Referring now to FIG. 6A, a cross-sectional illustration of a package substrate 601 is shown, in accordance with an embodiment. In an embodiment, the package substrate 601 may include a core and buildup layers over and under the core. The core may comprise glass or any other suitable core material. In an embodiment, pads 620 may be provided over a top surface of the package substrate 601. The pads 620 may be referred to as core pads 620 since they will couple to the cores of the overlying dies added in a subsequent processing operation. In an embodiment, the core pads 620 may include holes 625. The holes 625 may pass entirely through the thickness of the core pads 620 to expose a portion of the package substrate 601. In an embodiment, the holes 625 may be at the axial center of the core pads 620. In an embodiment, the holes 625 may be high aspect ratio holes. For example, a depth of the holes 625 may be greater than a width of the holes 625.

Referring now to FIG. 6B, a cross-sectional illustration of the package substrate 601 after a cavity 655 is formed into the top surface of the package substrate 601 is shown, in accordance with an embodiment. In an embodiment, the cavity 655 may be formed with any suitable process. For example, an etching process, a laser drilling process, or the like may be used to form the cavity 655. While the sidewalls of the cavity 655 are shown as being substantially vertical, the sidewalls may be sloped in some embodiments. In the illustrated process flow, the cavity 655 is shown as being formed after the core pads 620 are formed. However, in some embodiments, the cavity 655 may be formed before the core pads 620 are formed.

Referring now to FIG. 6C a cross-sectional illustration of the package substrate 601 after a bridge 650 is provided in the cavity 655 is shown, in accordance with an embodiment. The bridge 650 may be placed in the cavity 655 with a pick and place operation. While shown as being in direct contact with the package substrate 601, it is to be appreciated that intervening layers (e.g., adhesives, etc.) may be provided between the bridge 650 and the package substrate 601. The bridge 650 may include high density routing (not shown) in order to couple together dies that are added in a subsequent processing operation.

In an embodiment, a plurality of pads 610 may be provided over a top surface of the bridge 650. The pads 610 may be referred to as bridge pads 610 since they are formed on the bridge 650. In an embodiment, a dimension of the bridge pads 610 may be smaller than a dimension of the core pads 620. For example, a diameter of the bridge pads 610 may be up to approximately 40 μm. In an embodiment, the top surface of the bridge pads 610 may be substantially coplanar with a top surface of the core pads 620.

Referring now to FIG. 6D, a cross-sectional illustration of the package substrate 601 after a solder plating process is shown, in accordance with an embodiment. As shown, solder 621 may be plated on the core pads 620. The solder 621 may not fill the hole 625 in some embodiments. Similarly, solder 611 may be plated on the bridge pads 610. In an embodiment, a thickness of the solder 611 may be substantially similar to a thickness of the solder 621. The solder 611 and 621 may be a tin based solder or any other suitable solder formulation.

Referring now to FIG. 6E, a cross-sectional illustration of the package substrate 601 after a solder reflow process is shown, in accordance with an embodiment. In an embodiment, the reflow process may result in the top surfaces of the solder 621 and 611 being rounded due to surface tension effects. In a particular embodiment, a topmost surface of the solder 621 is substantially coplanar with a topmost surface of the solder 611. As such, the rBTV of the package is minimized.

In an embodiment, the solder 621 may flow into the holes 625. The solder 621 may completely fill the holes 625 so that a portion of the solder 621 contacts the package substrate 601. In other embodiments, the solder 621 partially fills the holes 625. More generally, the solder 621 may be described as spanning across the width of the holes 625.

Referring now to FIG. 6F, a cross-sectional illustration of an electronic package 600 after attachment of dies 640A and 640B is shown, in accordance with an embodiment. As shown, the dies 640A and 640B may be coupled to the package substrate by both the core bumps 620 and the bridge bumps 610. The bridge 650 serves to communicatively couple the die 640A to the die 640B. The dies 640 may be attached to the package substrate 601 using any attachment processes. Due to the minimized rBTV, the attachment process is simplified. The dies 640 may be any type of die, such as compute dies, memory dies, or the like.

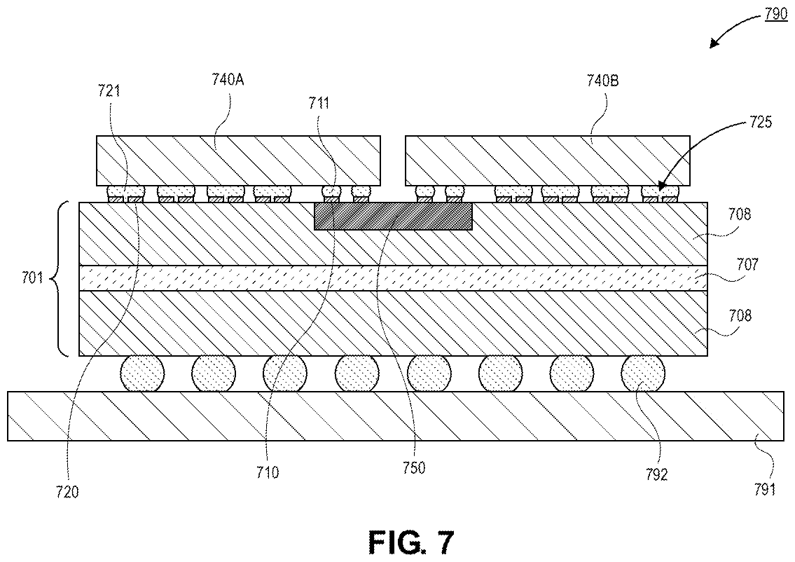

Referring now to FIG. 7, a cross-sectional illustration of an electronic system 790 is shown, in accordance with an embodiment. In an embodiment, the electronic system 790 comprises a board 791, such as a printed circuit board (PCB). The board 791 may be coupled to a package substrate 701 through interconnects 792, such as solder balls, sockets, or the like. In an embodiment, the package substrate 701 may comprise a core 707 and buildup layers 708 above and below the core 707. The core 707 may comprise glass or any other suitable core material.

In an embodiment, a bridge 750 is embedded in the package substrate 701. The bridge 750 may include high density routing (not shown) that communicatively couples the first die 740A to the second die 740B. The dies 740 may be any type of die, such as compute dies, memory dies, or the like. In an embodiment, solder 711 may couple the dies 740 to first pads 710 on the bridge 750. The dies 740 may further be coupled to the package substrate 701 by solder 721 and second pads 720. The second pads 720 may include holes 725 that are at least partially filled by the solder 721. The first pads 710 may be smaller than the second pads 720.

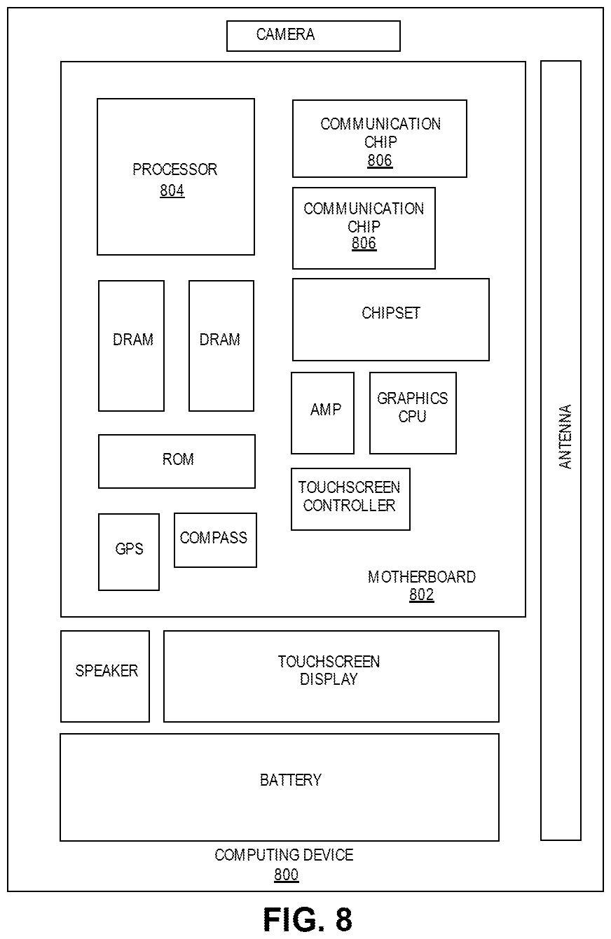

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises bridge bumps and core bumps, where the core bumps include holes that are at least partially filled by solder, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises bridge bumps and core bumps, where the core bumps include holes that are at least partially filled by solder, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an interconnect, comprising: a substrate; a pad over the substrate; a hole through the pad, wherein the hole exposes a portion of the substrate; and a solder over the pad, wherein the solder bridges across the hole through the pad.

Example 2: the interconnect of Example 1, wherein the solder fully fills the hole.

Example 3: the interconnect of Example 1, wherein the solder partially fills the hole.

Example 4: the interconnect of Examples 1-3, wherein a width of the hole is less than a thickness of the pad.

Example 5: the interconnect of Example 4, wherein the width of the hole is up to half the thickness of the pad.

Example 6: the interconnect of Example 4 or Example 5, wherein the width of the hole is up to approximately 15 μm.

Example 7: the interconnect of Examples 4-6, wherein an outer width of the pad is up to approximately 80 μm.

Example 8: the interconnect of Examples 1-7, wherein the solder comprises tin and the pad comprises copper.

Example 9: the interconnect of Examples 1-8, wherein the substrate is a package substrate.

Example 10: the interconnect of Example 9, wherein the package substrate is coupled to a processor of a computing system.

Example 11: the interconnect of Example 9, further comprising: a board coupled to the package substrate; and a die coupled to the package substrate, wherein the solder couples the die to the package substrate.

Example 12: an electronic package, comprising: a package substrate; a bridge embedded in the package substrate; a first pad on the bridge; and a second pad on the package substrate adjacent to the bridge, wherein the second pad comprises a hole through the second pad.

Example 13: the electronic package of Example 12, wherein the hole is at a center of the second pad.

Example 14: the electronic package of Example 12 or Example 13, wherein a width of the first pad is smaller than a width of the second pad.

Example 15: the electronic package of Example 14, wherein the width of the first pad is up to approximately 40 μm, and wherein the width of the second pad is up to approximately 80 μm.

Example 16: the electronic package of Examples 12-15, wherein a width of the hole is less than a thickness of the second pad.

Example 17: the electronic package of Example 16, wherein the width of the hole is up to half the thickness of the second pad.

Example 18: the electronic package of Examples 12-17, further comprising: a first reflown solder on the first pad; and a second reflown solder on the second pad.

Example 19: the electronic package of Example 18, wherein a top surface of the first reflown solder is approximately coplanar with a top surface of the second reflown solder.

Example 20: the electronic package of Example 18 or Example 19, wherein the second reflown solder at least partially fills the hole.

Example 21: the electronic package of Example 20, wherein the second reflown solder fully fills the hole.

Example 22: the electronic package of Examples 12-21, further comprising: a first die coupled to the electronic package; a second die coupled to the electronic package, wherein the bridge communicatively couples the first die to the second die; and a board coupled to the electronic package.

Example 23: an electronic system, comprising: a board; a package substrate coupled to the board; a bridge embedded in the package substrate; first pads on the bridge; second pads on the package substrate, wherein the second pads comprise holes through the second pads; a first die coupled to the electronic system by first pads and second pads; and a second die coupled to the electronic system by first pads and second pads.

Example 24: the electronic system of Example 23, wherein a solder is provided over the first pads and the second pads, and wherein the solder at least partially fills the holes in the second pads.

Example 25: the electronic system of Example 23 or Example 24, wherein the package substrate comprises a glass core.

What is claimed is:

1. An interconnect, comprising:
a substrate;
a pad over the substrate;
a hole through the pad, wherein the hole exposes a portion of the substrate; and
a solder over the pad, wherein the solder bridges across the hole through the pad.

2. The interconnect of claim 1, wherein the solder fully fills the hole.

3. The interconnect of claim 1, wherein the solder partially fills the hole.

4. The interconnect of claim 1, wherein a width of the hole is less than a thickness of the pad.

5. The interconnect of claim 4, wherein the width of the hole is up to half the thickness of the pad.

6. The interconnect of claim 4, wherein the width of the hole is up to approximately 15 μm.

7. The interconnect of claim 4, wherein an outer width of the pad is up to approximately 80 μm.

8. The interconnect of claim 1, wherein the solder comprises tin and the pad comprises copper.

9. The interconnect of claim 1, wherein the substrate is a package substrate.

10. The interconnect of claim 9, wherein the package substrate is coupled to a processor of a computing system.

11. The interconnect of claim 9, further comprising:
a board coupled to the package substrate; and
a die coupled to the package substrate, wherein the solder couples the die to the package substrate.

12. An electronic package, comprising:
a package substrate;
a bridge embedded in the package substrate;
a first pad on the bridge; and
a second pad on the package substrate adjacent to the bridge, wherein the second pad comprises a hole through the second pad.

13. The electronic package of claim 12, wherein the hole is at a center of the second pad.

14. The electronic package of claim 12, wherein a width of the first pad is smaller than a width of the second pad.

15. The electronic package of claim 14, wherein the width of the first pad is up to approximately 40 μm, and wherein the width of the second pad is up to approximately 80 μm.

16. The electronic package of claim 12, wherein a width of the hole is less than a thickness of the second pad.

17. The electronic package of claim 16, wherein the width of the hole is up to half the thickness of the second pad.

18. The electronic package of claim 12, further comprising:
a first reflown solder on the first pad; and
a second reflown solder on the second pad.

19. The electronic package of claim 18, wherein a top surface of the first reflown solder is approximately coplanar with a top surface of the second reflown solder.

20. The electronic package of claim 18, wherein the second reflown solder at least partially fills the hole.

21. The electronic package of claim 20, wherein the second reflown solder fully fills the hole.

22. The electronic package of claim 12, further comprising:
a first die coupled to the electronic package;
a second die coupled to the electronic package, wherein the bridge communicatively couples the first die to the second die; and
a board coupled to the electronic package.

23. An electronic system, comprising:
a board;
a package substrate coupled to the board;
a bridge embedded in the package substrate;
first pads on the bridge;
second pads on the package substrate, wherein the second pads comprise holes through the second pads;
a first die coupled to the electronic system by first pads and second pads; and
a second die coupled to the electronic system by first pads and second pads.

24. The electronic system of claim 23, wherein a solder is provided over the first pads and the second pads, and wherein the solder at least partially fills the holes in the second pads.

25. The electronic system of claim 23, wherein the package substrate comprises a glass core.
